(19) United States
(12) Patent Application Publication
(10) Pub. No.: US 2026/0280567 A1
(43) Pub. Date: Sep. 17, 2026

(54) CLOCK AND DATA RECOVERY FOR HIGH-SPEED SERIAL COMMUNICATION APPLICATIONS

(71) Applicant: Raytheon Company, Arlington, VA (US)

(72) Inventors: Alan Ronald Holden, Celina, TX (US); Lawrence Jeffrey Kushner, Ivins, UT (US)

(21) Appl. No.: 19/078,070

(22) Filed: Mar. 12, 2025

(51) Int. Cl. H03K 19/21; H03L 7/089; H04L 7/033

(52) U.S. Cl. CPC H03K 19/21; H03L 7/089; H04L 7/0337

(57) ABSTRACT

An apparatus for clock and data recovery (CDR) from a high-speed serial data stream is configured to operate over a wide range of data rates without the use of voltage-controlled oscillators (VCOs) or variable-delay gates (as in a delay-locked loop). The clock may be centered within the data eye by detecting the phase relationship between the data and clock with an at-rate 2- or 4-quadrant phase detector driving an analog loop filter, low-speed digital control loop, and phase interpolator. The phase interpolator may rotate the reference clock to be centered within the data eye for a low bit error rate. The CDR may track out frequency errors between the reference clock and incoming data stream without losing lock or loss of data. In integrated circuit implementations, the CDR consumes low die area due to the lack of VCOs.

### TECHNICAL FIELD

This disclosure relates generally to communication systems and processes. More specifically, this disclosure relates to clock and data recovery for high-speed serial communication applications.

### BACKGROUND

High-speed serial communication systems are used in various applications and help with communication at high data transfer rates. High-speed serial communication systems often rely on SERDES (serializer-de-serializer) to convert high-speed serial communications into parallel communications. A component of the SERDES is the clock and data recovery (CDR) unit. A CDR extracts clock information from an incoming data stream and samples the data with the recovered clock information in order to recover the information in the data stream.

### SUMMARY

This disclosure provides a clock and data recovery for high-speed serial communication applications.

In some examples, an apparatus includes a first memory element coupled to a first exclusive OR (XOR) gate configured to generate a first output and a second memory element coupled to a second XOR gate configured to generate a second output. An input of the first memory element is configured to receive a high-speed data signal input, and an input of the second memory element is configured to receive the high-speed data signal input.

Any single one or any combination of the following features may be used with the above examples. The apparatus may include a first variable capacitor coupled to an output of the first XOR gate and configured to provide a first analog output to a comparator and a second variable capacitor coupled to an output of the second XOR gate and configured to provide a second analog output to the comparator. The apparatus may include a third memory element coupled to a third XOR gate configured to generate a third output and a fourth memory element coupled to a fourth XOR gate configured to generate a fourth output. An input of the third memory element can be configured to receive the high-speed data signal input, and an input of the fourth memory element can be configured to receive the high-speed data signal input. The first output and the second output can be combined using a first variable capacitor to produce a first linear output, and the third output and the fourth output can be combined using a second variable capacitor to produce a second linear output. The first variable capacitor may be configured to provide the first linear output to a comparator, and the second variable capacitor may be configured to provide the second linear output to the comparator. Each XOR gate may be a complementary metal-oxide semiconductor (CMOS) logic gate or a current mode logic (CML) gate. The input of the first memory element and the input of the second memory element may be configured to receive a reference clock signal.

In other examples, a system includes an amplifier configured to receive and amplify a data input signal to produce a high-speed data signal and a phase detector configured to convert the high-speed data signal to an analog signal. The phase detector includes a first memory element coupled to a first XOR gate configured to generate a first output and a second memory element coupled to a second XOR gate configured to generate a second output. An input of the first memory element is coupled to the amplifier and configured to receive the high-speed data signal, and an input of the second memory element is coupled to the amplifier and configured to receive the high-speed data signal. The system also includes a single de-multiplexor coupled to the input of the first memory element and the input of the second memory element and configured to receive the high-speed data signal. The system further includes a comparator coupled to one or more outputs of the phase detector and an up/down counter and configured to produce a low-speed digital signal. In addition, the system includes a phase interpolator coupled to an output of the up/down counter and configured to provide a phase interpolator output to a first memory element input of the first memory element and a second memory element input of the second memory element.

Any single one or any combination of the following features may be used with the above examples. The phase detector may include a third memory element coupled to a third XOR gate configured to generate a third output and a fourth memory element coupled to a fourth XOR gate configured to generate a fourth output. An input of the third memory element can be configured to receive the high-speed data signal, and an input of the fourth memory element can be configured to receive the high-speed data signal. The first output and the second output can be combined using a first variable capacitor to produce a first linear output, and the third output and the fourth output can be combined using a second variable capacitor to produce a second linear output. The comparator can be configured to receive the first linear output and the second linear output and produce a comparator output. The comparator output may be provided to an up/down counter and a decoder to produce the low-speed digital signal. The phase interpolator may be configured to produce the phase interpolator output based on the low-speed digital signal. The system may include a quadrature clock generator configured to generate reference clock signals from a reference clock and provide the reference clock signals to the phase interpolator.

In still other examples, a method includes providing a high-speed data signal to a phase detector. The phase detector includes a first memory element coupled to a first XOR gate configured to generate a first output and a second memory element coupled to a second XOR gate configured to generate a second output. An input of the first memory element is coupled to an amplifier and configured to receive a high-speed data signal, and an input of the second memory element is coupled to the amplifier and configured to receive the high-speed data signal. The method also includes providing a phase interpolator output to the phase detector using a phase interpolator and generating one or more analog signals using the phase detector based on the high-speed data signal and the phase interpolator output. The method further includes providing the one or more analog signals to a comparator to generate a low-speed digital signal and providing the low-speed digital signal to the phase interpolator. In addition, the method includes adjusting the phase interpolator output based on the low-speed digital signal.

Any single one or any combination of the following features may be used with the above examples. The phase detector may include a third memory element coupled to a third XOR gate configured to generate a third output and a fourth memory element coupled to a fourth XOR gate configured to generate a fourth output. An input of the third memory element can be configured to receive the high-speed data signal, and an input of the fourth memory element can be configured to receive the high-speed data signal. Generating the one or more analog signals may include combining the first output and the second output using a first variable capacitor to produce a first linear output and combining the third output and the fourth output using a second variable capacitor to produce a second linear output. The method may include generating reference clock signals using a quadrature clock generator and a reference clock and providing the reference clock signals to the phase interpolator to produce the phase interpolator output. Each XOR gate may be a CMOS logic gate or a CML gate. The method may include, after adjusting the phase interpolator output based on the low-speed digital signal, providing the phase interpolator output to a single de-multiplexor for sampling the high-speed signal.

Other technical features may be readily apparent to one skilled in the art from the following figures, descriptions, and claims.

### BRIEF DESCRIPTION OF THE DRAWINGS

For a more complete understanding of this disclosure, reference is made to the following description, taken in conjunction with the accompanying drawings, in which:

FIG. 1A illustrates an example de-serializer system in accordance with this disclosure;

FIG. 1B illustrates an example clock recovery system of the example de-serializer system of FIG. 1A in accordance with this disclosure;

FIG. 2 illustrates an example phase detector for a clock and data recovery system in accordance with this disclosure;

FIG. 3A illustrates an example exclusive OR (XOR) gate for a phase detector of a clock and data recovery system in accordance with this disclosure;

FIG. 3B illustrates an example memory element for a phase detector of a clock and data recovery system in accordance with this disclosure;

FIG. 4 illustrates another example phase detector for a clock and data recovery system in accordance with this disclosure;

FIG. 5 illustrates an example method for clock and data recovery using current-mode logic for high-speed serial communication applications according to this disclosure; and

FIG. 6 illustrates an example device for clock and data recovery using current-mode logic for high-speed serial communication applications in accordance with this disclosure.

### DETAILED DESCRIPTION

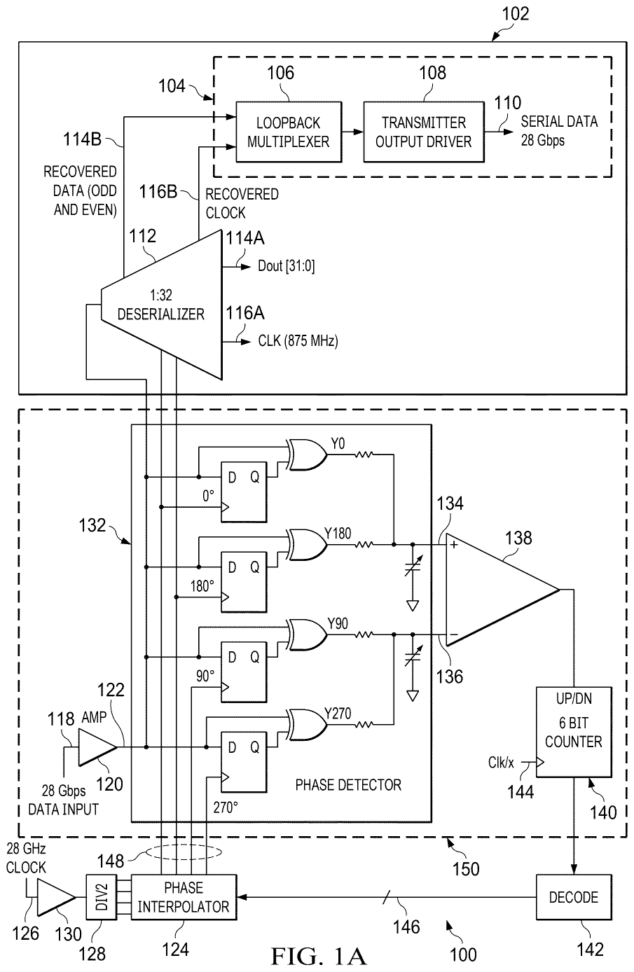

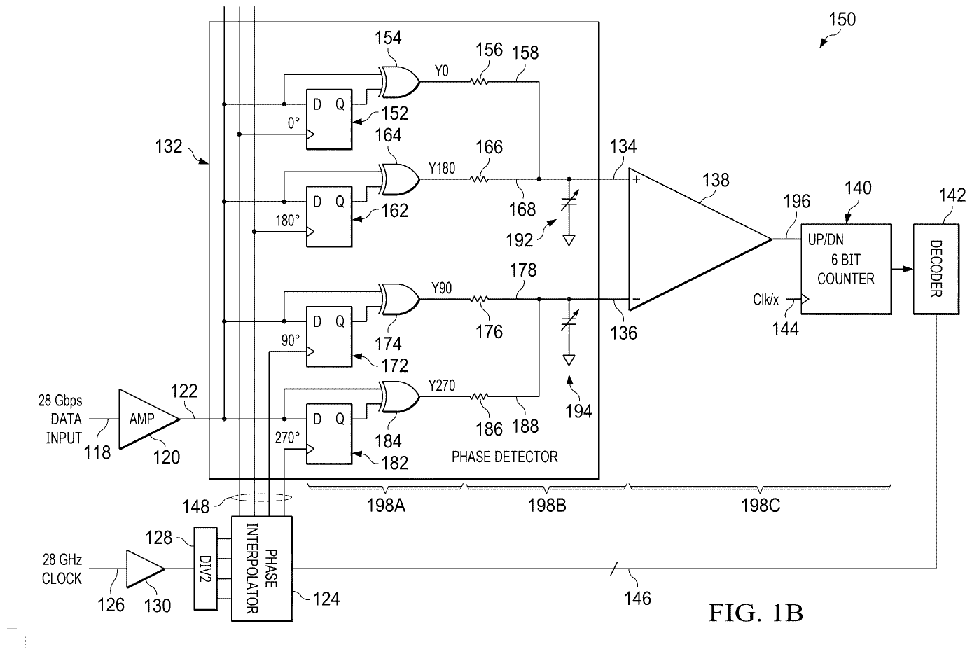

FIGS. 1 through 6, described below, and the various embodiments used to describe the principles of the present disclosure are by way of illustration only and should not be construed in any way to limit the scope of this disclosure. Those skilled in the art will understand that the principles of the present disclosure may be implemented in any type of suitably arranged device or system.

As noted above, high-speed serial communication systems are used in various applications and help with communication at high data transfer rates. High-speed serial communication systems often rely on SERDES (serializer-de-serializer) to convert high-speed serial communications into parallel communications. A component of the SERDES is the clock and data recovery (CDR) unit. A CDR extracts clock information from an incoming data stream and samples the data with the recovered clock information in order to recover the information in the data stream. However, high-speed CDR operations are often limited to a small range of data rates and are generally intolerant to frequency errors between an incoming data stream and a reference clock. The use of voltage controlled oscillators (VCOs) may mitigate this issue, but VCOs are often complex and can require a large area to provide acceptable performance. Additionally, to have low jitter, VCOs have narrow tuning range, making them inherently narrow band. To cover a wide band, a large number of VCOs need to be incorporated, requiring a large amount of die error.

This disclosure provides improved clock and data recovery systems and methods that address these or other issues. For example, embodiments of this disclosure can include a CDR system using current-mode logic that incorporates a mixed-signal phase detector into a phase interpolator-based clock and data recovery architecture. The CDR system can include a digital control loop that has a clock that is independent of the high-speed reference clock coupled to the phase interpolator. The CDR system need not use multiple de-multiplexors or any VCOs, meaning the CDR system may be VCO-less. This allows embodiments of this disclosure to have a wider operating frequency range, have a higher tolerance to frequency errors between an incoming high-speed data stream and a reference clock, and provide simple and robust at-rate phase detection.

FIG. 1A illustrates an example de-serializer system 100 in accordance with this disclosure. As shown in FIG. 1A, the de-serializer system 100 includes a de-serializer 102. The de-serializer 102 includes a sampler 104 having a loopback multiplexer 106 and a transmitter output driver 108 and is configured to produce a serial data output 110. The de-serializer 102 also includes a single de-multiplexer 112. The de-multiplexer 112 may be a 1:32 de-multiplexer or other de-multiplexer and is configured to produce a data output 114A, a clock output 116A, a half-rate recovered data 114B, and a half-rate recovered clock 116B. The recovered data 114B and the recovered clock 116B are input into the sampler 104, such as to the loopback multiplexer 106 for diagnostic analysis, to produce the serial data output 110. In some cases, the de-serializer 102 may be configured to convert the serialized data of a high-speed data signal 122 back to its original object or data structure, such as back into parallel data streams. The transmitter output driver 108 amplifies the recovered data 114B and recovered clock 116B to produce the serial data output 110.

The de-serializer system 100 is configured to receive a data signal 118 and subsequently provide the data signal 118 to an amplifier 120 to produce a high-speed data signal 122. A phase interpolator 124 is configured to receive a reference clock 126 through a quadrature clock generator 128 and an optional amplifier 130. The quadrature clock generator 128 converts the reference clock 126 into separate reference clock signals at different phase degrees, such as 0°, 90°, 180°, and 270°.

In some embodiments, the phase interpolator 124 may produce an interpolated phase using a phase difference of input signals, such as between the reference clock signals (e.g., between the four quadrature phase inputs at 0°, 90°, 180°, and 270°generated by the quadrature clock generator 128). The phase interpolator 124 may use the two most significant bits (MSBs) of the control signal select the quadrant by selecting the correct sign of the quadrature components. The phase interpolator 124 may use the remaining least significant bits (LSBs) to select the fraction of the input clocks to combine and phase shifts below π/4. The weights chosen by the LSBs may be trigonometrically weighted.

The high-speed data signal 122 is provided as input into a phase detector 132. For example, the high-speed data signal 122 may be provided to the phase detector 132 at the full rate of the high-speed data signal 122. In other words, the high-speed data signal 122 may not be passed through a de-multiplexer prior to being input into the phase detector 132. This reduces the complexity of the de-serializer system 100 as fewer phase detectors and de-multiplexers are used to recover data from the high-speed data signal 122. The phase detector 132 is configured to produce a first linear output 134 and a second linear output 136.

The first linear output 134 and the second linear output 136 are provided to a comparator 138. The comparator 138 converts the first linear output 134 and the second linear output into a low-speed digital signal 146. In some embodiments, the comparator 138 may be one or more one-bit analog-to-digital converters that convert the first linear output 134 and the second linear output 136 into a single low-speed digital signal 146. The comparator 138 is coupled to a counter 140 and a decoder 142. The counter 140 is also coupled to a counter clock 144 that is independent from other clocks in the de-serializer system 100. The counter 140 may be a digital up/down counter configured to provide additional filtering and integration of the low-speed digital signal 146. The decoder 142 may decode the low-speed digital signal 146 that is input into the phase interpolator 124. Functionally, the comparator 138, the counter 140, and the decoder 142 together operate as a digital control loop that provides feedback to the phase interpolator 124. The digital control loop may be fine-tuned to track larger frequency differences between the reference clock and the data clock from the high-speed data signal, such as by using a faster counter clock 144. The use of a faster counter clock 144 allows the digital control loop to take smaller steps in the phase interpolator 124 for less jitter when locked. As such, the use of the phase interpolator 124 allows the de-serializer system 100 to have a wide frequency of operation with low jitter without the use of VCOs. The digital control loop (the comparator 138, the counter 140, and the decoder 142) also allows for at-speed phase detection in the phase detector 132 using a single de-multiplexer 112 rather than requiring several de-multiplexers operating at lower speeds to prevent phase errors.

The phase interpolator 124 uses the low-speed digital signal 146 and the output from the quadrature clock generator 128 to produce a phase interpolator output 148. The phase interpolator output 148 is provided to the phase detector 132 as input, as well as to the de-serializer 102, such as to the de-multiplexer 112, as input.

FIG. 1B illustrates an example clock recovery (CDR) system 150 of the example de-serializer system of FIG. 1A in accordance with this disclosure. As shown in FIG. 1B, the CDR system 150 includes a close-up view of the phase detector 132. In this example, the phase detector 132 is a mixed-signal phase detector, meaning that a signal being processed in the phase detector 132 can be converted between digital and analog formats. The phase detector 132 includes a first memory element 152 coupled to a first exclusive OR (XOR) gate 154 that is configured to produce a first analog signal 158. Similarly, the phase detector 132 includes a second memory element 162 coupled to a second XOR gate 164 that is configured to produce a second analog signal 168. The phase detector 132 may additionally include a third memory element 172 coupled to a third XOR gate 174 that is configured to produce a third analog signal 178 and a fourth memory element 182 coupled to a fourth XOR gate 184 that is configured to produce a fourth analog signal 188. In some cases, the phase detector 132 may include the same D-type flip flops or other differential logic cells as a first stage of the de-multiplexer 112. This allows for clock-to-data timing to be tracked despite process and temperature variations to provide better performance and an improved sampling for eye opening of the high-speed data signal 122.

In some embodiments, the memory elements 152, 162, 172, 182 are D type flip flops configured to receive data input from a clock signal and produce an output using a rising edge of the clock signal. The first memory element 152, the second memory element 162, the third memory element 172, and the fourth memory element 182 may receive four-phase clocks that are at half rate, such as half of the rate of the high-speed data signal 122. For example, if the rate of the high-speed data signal 122 is 28 Gbps, each of the memory elements 152, 162, 172, 182 may be clocked at 14 GHz, sampling the input data. Also, in some cases, the first memory element may be at a 0° phase shift. The second memory element may be at a 90° phase shift, the third memory element may be at a 180° phase shift, and the fourth memory element may be at a 270° phase shift.

The XOR gates 154, 164, 174, 184 may be complementary metal-oxide semiconductor (CMOS) logic gates and can be configured to produce delay signals based on the mismatch of the Q output from the memory elements 152, 162, 172, 182 and the received high-speed data signal 122. In other words, each of the XOR gates 154, 164, 174, 184 produces a signal pulse with a duration based on the length of the mismatch between the Q output and the high-speed data signal 122. Each of the XOR gates 154, 164, 174, 184 is coupled to a resistor that is part of an analog integrator, such as a first filter resistor 156, a second filter resistor 166, a third filter resistor 176, and a fourth filter resistor 186. The first analog signal 158 and the second analog signal 168 are combined at a first variable capacitor 192, where the first filter resistor and the first variable capacitor 192 are a first analog integrator and where the second filter resistor and the first variable capacitor 192 are a second analog integrator. The signals output from each of the first XOR gate 154 and the second XOR gate 164 are passed through their respective analog integrators and combined to generate the first linear output 134. Similarly, the third analog signal 178 and the fourth analog signal 188 may be filtered and combined at a second variable capacitor 194 to generate the second linear output 136. The analog integrators, such as the filter resistor and variable capacitor combinations, remove high frequency components of the signals, which aid in converting to a low-speed digital signal in the comparator 138.

The outputs of the phase detector 132, such as the first linear output 134 and the second linear output 136, being integrated in an analog domain allows for a lower sampling frequency, such as in the comparator 138 and at the counter 140. The first linear output 134 and the second linear output 136 are input into the comparator 138 to generate a comparator signal 196 that is input into the counter 140. Due to the decreased sampling speed of the output of the phase detector 132, the counter 140 is able to use an independent counter clock 144 operating at a lower frequency without being burdened by a phase requirement from the reference clock signal 126.

As shown in FIG. 1B, the high-speed data signal 122 undergoes signal changes as it is processed through the phase detector 132 and the comparator 138. When the high-speed data signal 122 enters the phase detector 132 and is split to each of the first memory element 152, second memory element 162, third memory element 172, and fourth memory element 182, the signal is in a high-speed digital signal phase 198A. After exiting the respective R-C integrator, the signal is in an analog signal phase 198B. Subsequently, after the comparator 138, the signal is in a low-speed digital signal phase 198C.

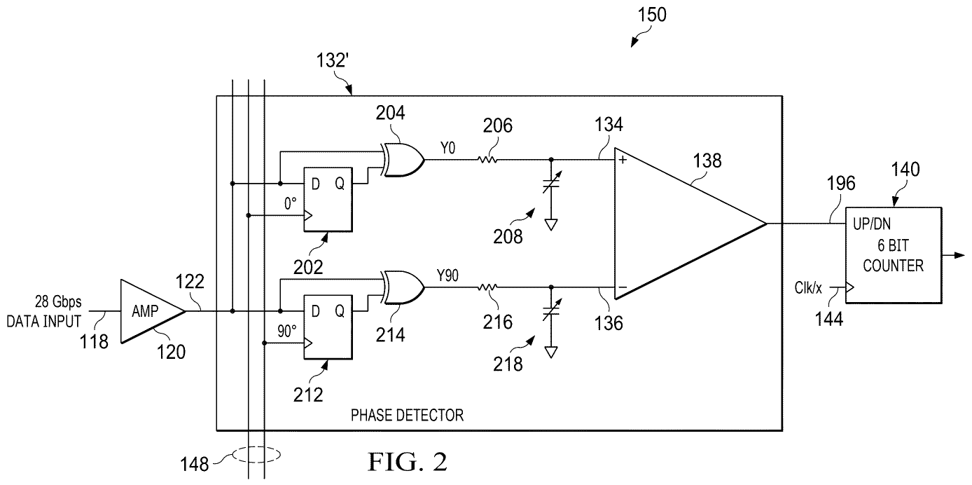

Although FIGS. 1A and 1B illustrate one example of a de-serializer system 100 using CMOS logic low-speed serial communication applications, various changes may be made to FIGS. 1A and 1B. For example, various components in FIGS. 1A and 1B may be combined, further subdivided, replicated, omitted, or rearranged and additional components may be added according to particular needs. As a particular example, the phase detector may include fewer clocks (as shown in FIG. 2). Also, while the phase detector 132 is shown in FIGS. 1A and 1B as being single-ended, other embodiments may use current mode logic (CML) or other differential logic cells.

FIG. 2 illustrates an example phase detector 132′ for a clock and data recovery system in accordance with this disclosure. The phase detector 132′ is configured similarly to the phase detector 132 of FIGS. 1A and 1B except as otherwise described. Further, phase detector 132′ may be used to replace the phase detector 132 in FIGS. 1A and 1B. As shown in FIG. 2, the phase detector 132′ is a two-quadrant version of the phase detector 132 of FIGS. 1A and 1B and includes only 0° and 90° clocks and XOR gates, which may allow for a reduced buffer chain on data and clock signals. The phase detector 132′ includes a first memory element 202 coupled to a first XOR gate 204 configured to produce a first analog signal 206. The first analog signal 206 is processed using a first variable capacitor 208 to generate the first linear output 134. Similarly, the phase detector 132′ includes a second memory element 212 coupled to a second XOR gate 214 configured to generate a second analog signal 216. The second analog signal 216 is processed using a second variable capacitor 218 to generate the second linear output 136. Here, however, the first analog signal 206 and the second analog signal 216 are not combined.

Both the first linear output 134 and the second linear output 136 are input into the comparator 138 to generate the comparator signal 196 that is input into the counter 140. The data signal 118 is amplified using an amplifier 120 to generate the high-speed data signal 122 that is provided to an input of the first memory element 202 and an input of the second memory element 212. The reduced two-quadrant phase detector 132′ here therefore allows for reduced power consumption and uses less area.

Although FIG. 2 illustrates one example of a phase detector 132′ for the CDR system 150 using current-mode logic, various changes may be made to FIG. 2. For example, various components in FIG. 2 may be combined, further subdivided, replicated, omitted, or rearranged and additional components may be added according to particular needs.

To facilitate conversion of a high-speed data signal into an analog signal in a mixed-signal phase detector of a clock and data recovery system, various configurations of XOR gates may be used. In some embodiments, differential or CML-based XOR gates may be used.

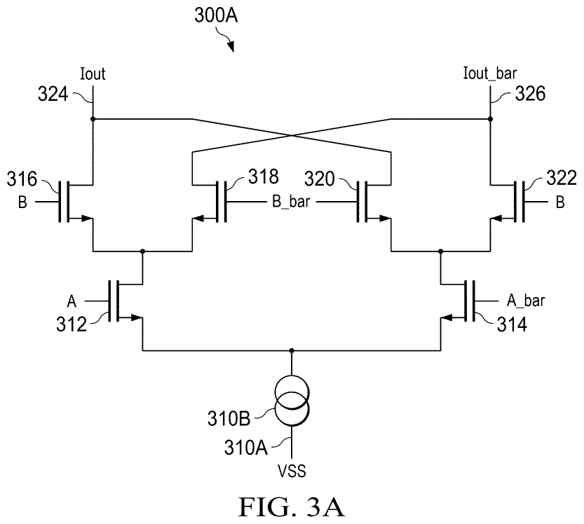

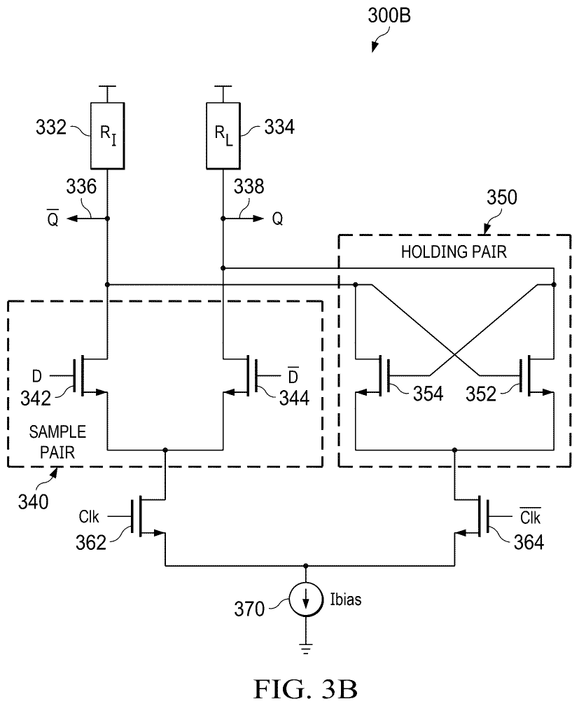

FIG. 3A illustrates an example exclusive OR (XOR) gate 300A for a phase detector of a clock and data recovery system in accordance with this disclosure. FIG. 3B illustrates an example memory element 300B for a phase detector of a clock and data recovery system in accordance with this disclosure. In particular, FIG. 3A illustrates the XOR gate 300A implemented in current-mode logic (CML) for higher speed operation, and FIG. 3B illustrates a CML D-type flip flop logic cell (memory element) also employed for higher speed operation. The CML XOR gate 300A may be used for one or all of the exclusive OR gates shown in FIGS. 1A through 2, and the CML D-type flip flop logic cell (CML D-FF) 300B may be used for one or all of the memory elements shown in FIGS. 1A through 2.

As shown in FIG. 3A, the CML XOR gate 300A includes a voltage source 310A coupled to a current source 310B which are subsequently coupled to a first transistor 312 and a second transistor 314 in parallel branches. In some cases, the first transistor 312 and the second transistor 314 may be field effect transistors. Alternatively, the first transistor and the second transistor may be bipolar transistors which may allow for high speed operation, particularly if the bipolar transistors are implemented in silicon germanium or indium phosphide. The source of the first transistor 312 and the second transistor 314 are coupled to the current source 310B. The drain of the first transistor 312 is coupled to a third transistor 316 and a fourth transistor 318 that are in parallel. Similarly, the drain of the second transistor 314 is coupled to a fifth transistor 320 and a sixth transistor 322 that are in parallel. The drain of the third transistor 316 is coupled to the drain of the fifth transistor 320 to generate a first current output 324 while the drain of the fourth transistor 318 is coupled to the drain of the sixth transistor 322 to generate a second current output 326. The CML XOR gate 300A is a CML XOR gate that uses current-mode logic in which logic states are represented by currents rather than voltages. For instance, the CML XOR gate 300A may rely on differential current paths to represent logic states. The differential current paths involve the difference between two voltage levels, improving noise immunity and signal integrity. This also allows for high-speed operation of the CML XOR gate 300A.

As shown in FIG. 3B, the CML D-FF 300B uses a pair of parallel field effect transistors. The CML D-FF 300B includes a first load resistor 332 and a second load resistor 334 that produce a first signal 336 (Q) and a second signal 338 (Q), respectively. The first load resistor 332 and the second load resistor 334 are coupled to a sample pair 340. For example, the first load resistor 332 is coupled to a drain of a first sample transistor 342, and the second load resistor 334 is coupled to a drain of a second sample transistor 344. The first sample transistor 342 and the second sample transistor 344 are coupled to each other in parallel at their respective source. Similarly, the first load resistor 332 and the second load resistor 334 are further coupled to a hold pair 350. The hold pair 350 includes a first hold transistor 352 and a second hold transistor 354. A gate of the first hold transistor 352 is coupled to a drain of the second hold transistor 354, and a gate of the second hold transistor 354 is coupled to a drain of the first hold transistor 352. The first load resistor 332 is coupled to the drain of the second hold transistor 354, and the second load resistor 334 is coupled to the drain of the first hold transistor 352. The first hold transistor 352 and the second hold transistor 354 are coupled to each other in parallel at their respective source.

A first D flip flop transistor 362 is coupled to the sample pair 340, such as a drain of the first D flip flop transistor 362 is coupled to the source of the first sample transistor 342 and second sample transistor 344. A gate of the first D flip flop transistor 362 is coupled to a first D flip flop signal. Similarly, a second D flip flop transistor 364 is coupled to the hold pair 350, such as a drain of the second D flip flop transistor 364 is coupled to the source of the first hold transistor 352 and second hold transistor 354. A gate of the second D flip flop transistor 364 is coupled to a second D flip flop signal. A drain of the first D flip flop transistor 362 and a drain of the second D flip flop transistor 364 are coupled to each other in parallel and to a current bias 370. The CML D-FF 300B is a CML-based D-type flip flop that stores a single bit of data and latches when a clock input transitions. For instance, the CML D-FF 300B may use current switching for data storage and transfer.

As can be seen here, the CML circuits (the CML XOR gate 300A and the CML D-FF 300B) allow for the use of differential current outputs, resulting in higher speeds and better noise immunity. The CML XOR gate 300A and CML D-FF 300B may be used in the embodiments of the CDR systems described in the present disclosure.

Although FIGS. 3A and 3B illustrate example CML logic for a phase detector of a clock and data recovery system, various changes may be made to FIGS. 3A and 3B. For example, various components in FIGS. 3A and 3B may be combined, further subdivided, replicated, omitted, or rearranged and additional components may be added according to particular needs.

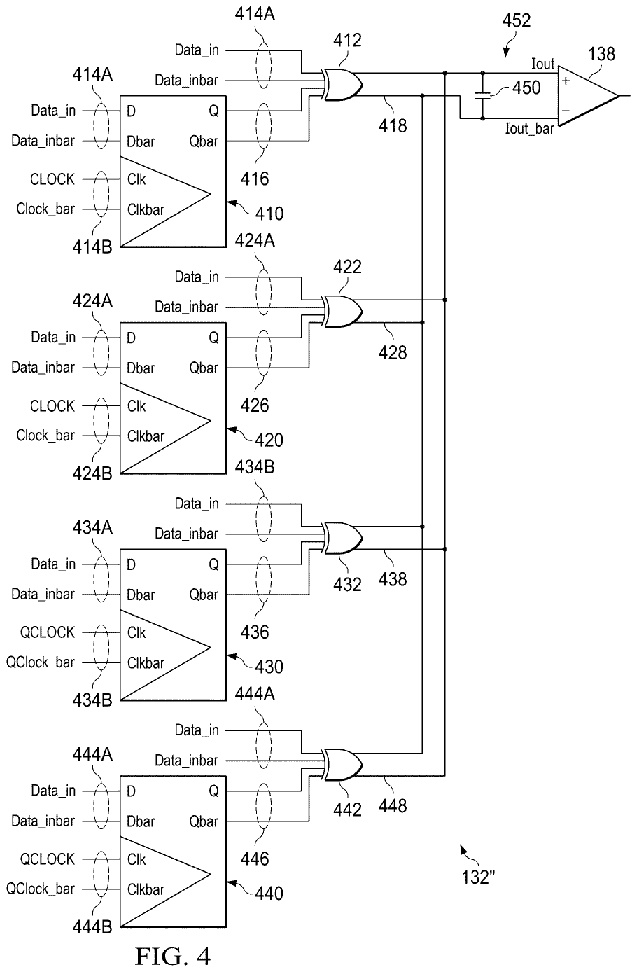

Note that other configurations of a CDR system are contemplated. For example, the phase detector may also be included in a CML implementation. FIG. 4 illustrates another example phase detector 132″ for a clock and data recovery system in accordance with this disclosure. As shown in FIG. 4, the phase detector 132″ includes a first memory element 410 and a second memory element 420. The phase detector 132″ may also include a third memory element 430 and a fourth memory element 440. The phase detector 132″ further includes a first XOR gate 412 coupled to the first memory element 410 and a second XOR gate 422 coupled to the second memory element 420. In addition, the phase detector 132″ may include a third XOR gate 432 coupled to the third memory element 430 and a fourth XOR gate 442 coupled to the fourth memory element 440. Each of the clocks have a respective data input and a clock input, such as when the first memory element 410 has a first data input 414A and a first memory element input 414B, the second memory element 420 has a second data input 424A and a second memory element input 424B, the third memory element 430 has a third data input 434A and a third memory element input 434B, and the fourth memory element 440 has a fourth data input 444A and a fourth memory element input 444B.

Each of the XOR gates is coupled to the data input of its respective clock. For example, the first XOR gate 412 receives the first data input 414A as input, the second XOR gate 422 receives the second data input 424A as input, the third XOR gate 432 receives the third data input 434A as input, and the fourth XOR gate 442 receives the fourth data input 444A as input. The XOR gates also receive clock signals from their respective clocks. For instance, the first XOR gate 412 receives the first digital output signal 416 as input, the second XOR gate 422 receives the second digital output signal 426 as input, the third XOR gate 432 receives the third digital output signal 436 as input, and the fourth XOR gate 442 receives the fourth digital output signal 446 as input.

The XOR gates are configured to generate parallel analog signals based on the received data signals and the clock signals. For example, the first XOR gate 412 generates a first analog signal 418, the second XOR gate 422 generates a second analog signal 428, the third XOR gate 432 generates a third analog signal 438, and the fourth XOR gate 442 generates a fourth analog signal 448. By using the differential, current-mode nature of CML logic, the outputs of the XOR gates 412, 422, 432, 442 may be summed together and integrated using the capacitor 450 across the output. The first analog signal 418, the second analog signal 428, the third analog signal 438, and the fourth analog signal 448 are combined at a capacitor 450 to generate a linear signal 452. This combination of different outputs of the XOR gates 412, 422, 432, 442 is possible due to the differential, current-mode nature of CML logic. The linear signal 452 may be provided to a comparator, such as the comparator 138, for further processing.

Each of the XOR gates may be the CML XOR gate 300A described in FIG. 3A. The D-FF may be the CML D-FF 300B of FIG. 3B. Further, the phase detector 132″ may be used to replace the phase detector 132 of FIGS. 1A-1B or be modified to be a two-quadrant phase detector as shown in the phase detector 132′ of FIG. 2.

Although FIG. 4 illustrates another example of a phase detector 132″ for a clock and data recovery system, various changes may be made to FIG. 4. For example, various components in FIG. 4 may be combined, further subdivided, replicated, omitted, or rearranged and additional components may be added according to particular needs.

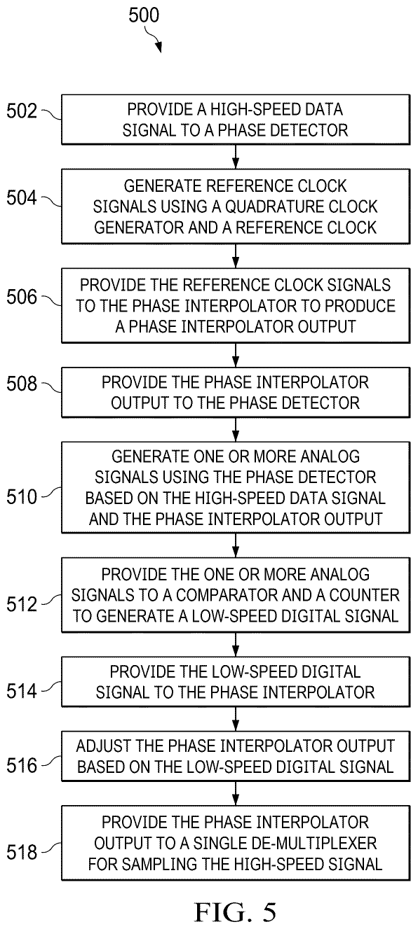

FIG. 5 illustrates an example method 500 for clock and data recovery using current-mode logic for high-speed serial communication applications according to this disclosure. For ease of explanation, the method 500 of FIG. 5 is described as being performed using the de-serializer system 100 of FIGS. 1A and 1B. However, the method 500 may be used with any other suitable system and any other suitable clock and data recovery system, such as a CDR system using the phase detector 132′ of FIG. 2 or the phase detector 132″ of FIG. 4.

As shown in FIG. 5, a high-speed data signal is provided to a phase detector at step 502. For example, a data signal 118 may be provided to an amplifier 120 to generate a high-speed data signal 122, which is input into a phase detector 132 of a CDR system 150. Reference clock signals are generated using a quadrature clock generator and a reference clock at step 504. For example, a reference clock 126 may be provided to a quadrature clock generator 128 after optional amplification at an optional amplifier 130. The quadrature clock generator 128 may convert the reference clock 126 into reference clock signals. The reference clock signals are provided to the phase interpolator to produce a phase interpolator output at step 506. For example, after generation in the quadrature clock generator 128, the reference clock signals (such as at 0°, 90°, 180°, and 270°) may be provided as input into a phase interpolator 124. The phase interpolator 124 may use the reference clock signals to generate a phase interpolator output 148.

The phase interpolator output is provided to the phase detector at step 508. For example, the phase interpolator output 148 generated by the phase interpolator 124 may be provided to the phase detector 132. For instance, the phase interpolator output 148 may be provided to each of a plurality of clocks disposed within the phase detector 132, such as the first memory element 152, the second memory element 162, the third memory element 172, and the fourth memory element 182. One or more analog signals are generated using the phase detector based on the high-speed data signal and the phase interpolator output at step 510. For example, the high-speed data signal 122 may be provided as input to each of the first memory element 152, the second memory element 162, the third memory element 172, and the fourth memory element 182 along with the phase interpolator output 148. Each clock may produce a clock signal that is input into a respective XOR gate, such as the first XOR gate 154, the second XOR gate 164, the third XOR gate 174, and the fourth XOR gate 184. Each XOR gate may also receive the high-speed data signal 122 as input and generate one or more analog signals, such as the first analog signal 158, the second analog signal 168, the third analog signal 178, and the fourth analog signal 188. These signals may be combined using a variable capacitor, such as the first variable capacitor 192 and the second variable capacitor 194.

The one or more analog signals are provided to a comparator to generate a low-speed digital signal at step 512. For example, the one or more analog signals, after combination in the first variable capacitor 192 and the second variable capacitor 194, may be provided to the comparator 138 as the first linear output 134 and the second linear output 136. The comparator 138 may generate a comparator signal 196 as a result of receiving the first linear output 134 and the second linear output 136 and provide the comparator signal 196 to the counter 140. The counter 140 may receive the comparator signal 196 and an independent clock signal from the counter clock 144 to adjust the comparator signal 196 up or down by a predetermined number of counts. The signal may be provided to the decoder 142 for decoding to generate the low-speed digital signal 146.

The low-speed digital signal is provided to the phase interpolator at step 514. For example, after decoding in the decoder 142, the low-speed digital signal 146 may be provided to the phase interpolator 124 as input. The phase interpolator output is adjusted based on the low-speed digital signal at step 516. For example, the phase interpolator 124 may use the low-speed digital signal 146 to adjust the generated phase interpolator output 148 using the reference clock signals from the quadrature clock generator 128. The phase interpolator 124 creates a weighted sum of its four quadrature input signals to rotate the incoming clock signal to any phase 0 to 360° (with resolution set by the number of bits) based on the low-speed digital control signal from the counter. The reference clock signals, such as the reference clock signals at 0°, 90°, 180°, and 270°, may be provided in the adjusted phase interpolator output 148.

The phase interpolator output is provided to a single de-multiplexor for sampling the high-speed signal at step 518. For example, the adjusted phase interpolator output 148 may be provided to the de-multiplexer 112 as well as the phase detector 132. The de-multiplexer 112 may use the adjusted phase interpolator output 148, which is a phase interpolation of the quadrature reference clock signals with an improved eye center of the high-speed data signal, to compensate for phase errors received in the data signal 118 and improving the accuracy of the recovered clock and data streams.

Although FIG. 5 illustrates one example of a method 500 for clock and data recovery using current-mode logic for high-speed serial communication applications, various changes may be made to FIG. 5. For example, while shown as a series of steps, various steps in FIG. 5 may overlap, occur in parallel, or occur any number of times (including zero times).

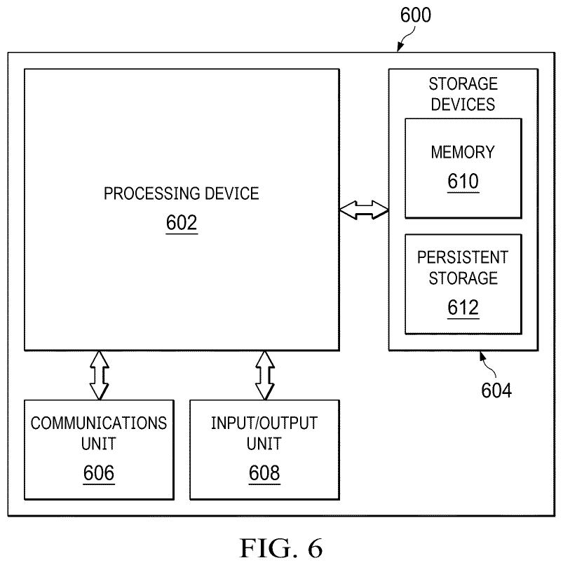

FIG. 6 illustrates an example device 600 for clock and data recovery using current-mode logic for high-speed serial communication applications according to this disclosure. One or more instances of the de-serializer system 100 of FIGS. 1A and 1B may, for example, be implemented in the device 600 (or one or more portions thereof). However, the functionality of the CDR system may be implemented in any other suitable device or system.

As shown in FIG. 6, the device 600 denotes a computing device or system that includes at least one processing device 602, at least one storage device 604, at least one communications unit 606, and at least one input/output (I/O) unit 608. The processing device 602 may execute instructions that can be loaded into a memory 610. The processing device 602 includes any suitable number(s) and type(s) of processors or other devices in any suitable arrangement. Example types of processing devices 602 include one or more microprocessors, microcontrollers, digital signal processors (DSPs), application-specific integrated circuits (ASICs), graphics processing units (GPUs), field programmable gate arrays (FPGAs), or discrete circuitry.

The memory 610 and a persistent storage 612 are examples of storage devices 604, which represent any structure(s) capable of storing and facilitating retrieval of information (such as data, program code, and/or other suitable information on a temporary or permanent basis). The memory 610 may represent a random access memory or any other suitable volatile or non-volatile storage device(s). The persistent storage 612 may contain one or more components or devices supporting longer-term storage of data, such as a read only memory, hard drive, Flash memory, or optical disc.

The communications unit 606 supports communications with other systems or devices. For example, the communications unit 606 can include a network interface card or a wireless transceiver facilitating communications over a wired or wireless network. The communications unit 606 may support communications through any suitable physical or wireless communication link(s). In particular, the communications unit 606 may include a serializer-de-serializer system that has the de-serializer system 100 of FIGS. 1A-1B.

The I/O unit 608 allows for input and output of data. For example, the I/O unit 608 may provide a connection for user input through a keyboard, mouse, keypad, touchscreen, or other suitable input device. The I/O unit 608 may also send output to a display or other suitable output device. Note, however, that the I/O unit 608 may be omitted if the device 600 does not require local I/O, such as when the device 600 can be accessed remotely or operated autonomously.

Although FIG. 6 illustrates one example of a device 600 that uses clock and data recovery using current-mode logic for high-speed serial communication applications, various changes may be made to FIG. 6. For example, computing devices and systems come in a wide variety of configurations, and FIG. 6 does not limit this disclosure to any particular computing device or system.

In some embodiments, various functions described in this patent document are implemented or supported by a computer program or other program that is formed from computer readable program code or instructions and that is embodied in a computer or machine readable medium. The phrases “computer readable program code” and “instructions” include any type of code, including source code, object code, and executable code. The phrases “computer readable medium” and “machine readable medium” include any type of medium capable of being accessed by a computer or other machine, such as read only memory (ROM), random access memory (RAM), a hard disk drive (HDD), a compact disc (CD), a digital video disc (DVD), or any other type of memory. A “non-transitory” computer or machine readable medium excludes wired, wireless, optical, or other communication links that transport transitory electrical or other signals. A non-transitory computer or machine readable medium includes media where data can be permanently stored and media where data can be stored and later overwritten, such as a rewritable optical disc or an erasable storage device.

It may be advantageous to set forth definitions of certain words and phrases used throughout this patent document. The terms “application” and “program” refer to one or more computer programs, software components, sets of instructions, procedures, functions, objects, classes, instances, related data, or a portion thereof adapted for implementation in a suitable computer code (including source code, object code, or executable code). The term “communicate,” as well as derivatives thereof, encompasses both direct and indirect communication. The terms “include” and “comprise,” as well as derivatives thereof, mean inclusion without limitation. The term “or” is inclusive, meaning and/or. The phrase “associated with,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, have a relationship to or with, or the like. The phrase “at least one of,” when used with a list of items, means that different combinations of one or more of the listed items may be used, and only one item in the list may be needed. For example, “at least one of: A, B, and C” includes any of the following combinations: A, B, C, A and B, A and C, B and C, and A and B and C.

The description in the present application should not be read as implying that any particular element, step, or function is an essential or critical element that must be included in the claim scope. The scope of patented subject matter is defined only by the allowed claims. Moreover, none of the claims invokes 35 U.S.C. § 112(f) with respect to any of the appended claims or claim elements unless the exact words “means for” or “step for” are explicitly used in the particular claim, followed by a participle phrase identifying a function. Use of terms such as (but not limited to) “mechanism,” “module,” “device,” “unit,” “component,” “element,” “member,” “apparatus,” “machine,” “system,” “processor,” or “controller” within a claim is understood and intended to refer to structures known to those skilled in the relevant art, as further modified or enhanced by the features of the claims themselves, and is not intended to invoke 35 U.S.C. § 112(f).

While this disclosure has described certain embodiments and generally associated methods, alterations and permutations of these embodiments and methods will be apparent to those skilled in the art. Accordingly, the above description of example embodiments does not define or constrain this disclosure. Other changes, substitutions, and alterations are also possible without departing from the spirit and scope of this disclosure, as defined by the following claims.

1. An apparatus comprising:
a first memory element coupled to a first exclusive OR (XOR) gate configured to generate a first output;
a second memory element coupled to a second XOR gate configured to generate a second output; and
a first variable capacitor coupled to the first XOR gate and the second XOR gate, the first variable capacitor configured to combine the first output and the second output and to provide an analog output to a comparator;
wherein an input of the first memory element is configured to receive a high-speed data signal input; and
wherein an input of the second memory element is configured to receive the high-speed data signal input.

2. The apparatus of claim 1, further comprising:
a first resistor coupled in series between an output of the first XOR gate and the first variable capacitor; and
a second resistor coupled in series between an output of the second XOR gate and the first variable capacitor.

3. The apparatus of claim 1, further comprising:
a third memory element coupled to a third XOR gate configured to generate a third output; and
a fourth memory element coupled to a fourth XOR gate configured to generate a fourth output;
wherein an input of the third memory element is configured to receive the high-speed data signal input; and
wherein an input of the fourth memory element is configured to receive the high-speed data signal input.

4. The apparatus of claim 3, wherein:
the first output and the second output are combined using the first variable capacitor to produce a first linear output, the first linear output representing the analog output; and
the third output and the fourth output are combined using a second variable capacitor to produce a second linear output.

5. The apparatus of claim 4, wherein:
the first variable capacitor is configured to provide the first linear output to the comparator; and
the second variable capacitor is configured to provide the second linear output to the comparator.

6. The apparatus of claim 1, wherein each XOR gate is a complementary metal-oxide semiconductor logic gate (CMOS) or a current mode logic (CML) gate.

7. The apparatus of claim 1, wherein the first memory element and the second memory element are further configured to receive a reference clock signal.

8. A system comprising:
an amplifier configured to receive and amplify a data input signal to produce a high-speed data signal;
a phase detector configured to convert the high-speed data signal to an analog signal, the phase detector comprising:
a first memory element coupled to a first exclusive OR (XOR) gate configured to generate a first output; and
a second memory element coupled to a second XOR gate configured to generate a second output;
wherein an input of the first memory element is coupled to the amplifier and configured to receive the high-speed data signal; and
wherein an input of the second memory element is coupled to the amplifier and configured to receive the high-speed data signal;
a single de-multiplexor coupled to the input of the first memory element and the input of the second memory element and configured to receive the high-speed data signal;
a comparator coupled to one or more outputs of the phase detector and an up/down counter and configured to produce a low-speed digital signal; and
a phase interpolator coupled to an output of the up/down counter and configured to provide a phase interpolator output to a first memory element input of the first memory element and a second memory element input of the second memory element.

9. The system of claim 8, wherein the phase detector further comprises:
a third memory element coupled to a third XOR gate configured to generate a third output; and
a fourth memory element coupled to a fourth XOR gate configured to generate a fourth output;
wherein an input of the third memory element is configured to receive the high-speed data signal; and
wherein an input of the fourth memory element is configured to receive the high-speed data signal.

10. The system of claim 9, wherein:
the first output and the second output are combined using a first variable capacitor to produce a first linear output; and
the third output and the fourth output are combined using a second variable capacitor to produce a second linear output.

11. The system of claim 10, wherein the comparator is configured to receive the first linear output and the second linear output and produce a comparator output.

12. The system of claim 11, wherein the comparator output is provided to the up/down counter and a decoder to produce the low-speed digital signal.

13. The system of claim 12, wherein the phase interpolator is configured to produce the phase interpolator output based on the low-speed digital signal.

14. The system of claim 8, further comprising:
a quadrature clock generator configured to generate reference clock signals from a reference clock and provide the reference clock signals to the phase interpolator.

15. A method comprising:
providing a high-speed data signal to a phase detector, the phase detector comprising:
a first memory element coupled to a first exclusive OR (XOR) gate configured to generate a first output; and
a second memory element coupled to a second XOR gate configured to generate a second output;
wherein an input of the first memory element is coupled to an amplifier and configured to receive the high-speed data signal; and
wherein an input of the second memory element is coupled to the amplifier and configured to receive the high-speed data signal;
providing a phase interpolator output to the phase detector using a phase interpolator;
generating one or more analog signals using the phase detector based on the high-speed data signal and the phase interpolator output;
providing the one or more analog signals to a comparator to generate a low-speed digital signal;
providing the low-speed digital signal to the phase interpolator; and
adjusting the phase interpolator output based on the low-speed digital signal.

16. The method of claim 15, wherein the phase detector further comprises:
a third memory element coupled to a third XOR gate configured to generate a third output; and
a fourth memory element coupled to a fourth XOR gate configured to generate a fourth output;
wherein an input of the third memory element is configured to receive the high-speed data signal; and
wherein an input of the fourth memory element is configured to receive the high-speed data signal.

17. The method of claim 16, wherein generating the one or more analog signals comprises:
combining the first output and the second output using a first variable capacitor to produce a first linear output; and
combining the third output and the fourth output using a second variable capacitor to produce a second linear output.

18. The method of claim 15, further comprising:
generating reference clock signals using a quadrature clock generator and a reference clock; and
providing the reference clock signals to the phase interpolator to produce the phase interpolator output.

19. The method of claim 15, wherein each XOR gate is a complementary metal-oxide semiconductor logic gate (CMOS) or a current mode logic (CML) gate.

20. The method of claim 15, further comprising:
after adjusting the phase interpolator output based on the low-speed digital signal, providing the phase interpolator output to a single de-multiplexor for sampling the high-speed data signal.
